(19) United States
(12) Patent Application Publication
(10) Pub. No.: US 2017/0167028 A1
(43) Pub. Date: Jun. 15, 2017

(54) SELENIZATION OR SULFURIZATION METHOD OF ROLL TO ROLL METAL SUBSTRATES

(71) Applicant: NUVOSUN, INC., Milpitas, CA (US)

(72) Inventors: Arthur C. WALL, Morgan Hill, CA (US); John Kwangyong KIM, San Jose, CA (US); Eugene BYKOV, San Jose, CA (US); Sam KAO, Los Altos, CA (US); Qiongzhong JIANG, Saratoga, CA (US); Bruce D. HACHTMANN, San Martin, CA (US)

(21) Appl. No.: 15/319,528

(22) PCT Filed: Jun. 8, 2015
(86) PCT No.: PCT/US2015/034639

§ 371 Date: Dec. 16, 2016

Related U.S. Application Data
(60) Provisional application No. 62/013,065, filed on Jun. 17, 2014.

(51) Int. Cl. C23C 16/54; C23C 16/46; C23C 16/52; C23C 16/30; C23C 16/448

(52) U.S. Cl. CPC C23C 16/545; C23C 16/305; C23C 16/4485; C23C 16/52; C23C 16/46

(57) ABSTRACT

Methods and systems are disclosed for processing a precursor material. The method includes introducing a substrate having a precursor material deposited on a surface of the substrate into a first zone of a vacuum chamber. The precursor material comprises copper, indium, and at least one of gallium, selenium, sulfur, sodium, antimony, boron, aluminum, and silver. The method further includes, within the first zone, heating the precursor material to a target reaction temperature within a range of about 270° C. to about 490° C. The method further includes maintaining a selenium vapor in a second zone of the vacuum chamber, and after heating the precursor material to the target reaction temperature, introducing the precursor material and the substrate to the second zone of the vacuum chamber.

### CROSS-REFERENCE TO RELATED APPLICATIONS

This application claims priority to U.S. Provisional Application No. 62/013,065, filed Jun. 17, 2014, the disclosure of which is hereby incorporated by reference in its entirety.

### BACKGROUND

Unless otherwise indicated herein, the materials described in this section are not prior art to the claims in this application and are not admitted to be prior art by inclusion in this section.

Unlike single crystalline silicon, copper indium diselenide (CuInSe₂ or CIS) is an effective light-absorbing material when deposited in thin layers (e.g. 1-5 μm) upon flexible substrates. In some applications, elements such as gallium or aluminum can be proportionally substituted for indium atoms within CIS to form materials such as CuIn₁₋ₓGaₓSe₂ (CIGS) or CuIn₁₋ₓAlₓSe₂ (CIAS). The foregoing groups of materials that are formed by replacing indium within CIS may generally be referred to as CIGS although it is understood for purposes of this document to include such materials as CIAS. Substitution of aluminum or gallium for indium, for example, can be used to increase an electronic bandgap of the material, which, depending on the application, may create a higher output voltage of a solar cell made from the material.

One way of forming CIGS films upon a substrate is via co-evaporation of constituent materials within a vacuum chamber. Co-evaporation involves heating copper, indium, gallium, aluminum, sulfur, or selenium source materials so that they evaporate within the vacuum chamber, condense upon a heated substrate, and react to form CIGS. The co-evaporation process may produce high-efficiency CIGS devices with smooth surfaces, but may be difficult to scale up for manufacturing.

Another process involves sputtering or co-deposition of a precursor film upon a substrate and then exposing the precursor film to selenium and/or sulfur vapor at high temperatures. Yet the CIGS films produced from this process are generally rougher than the surface of co-evaporated films. These rough surfaces may complicate the subsequent deposition of additional material layers to complete a solar cell or module.

### SUMMARY

Example embodiments provide methods configured to produce a CuInGaSe₂ (CIGS) film deposited upon a substrate. The example methods may beneficially produce a CIGS film with a smooth surface amenable to deposition of thin layers of CdS, for example, with a thickness on the order of about 50 nm to about 80 nm and/or deposition of thin transparent conductive oxides, for example, with a thickness on the order of about 200 nm to about 400 nm. For example, a CIGS film with a smooth surface may be formed by heating a precursor material such as a copper/indium/gallium alloy or mixture to a target reaction temperature before being exposed to a reactive vapor such as selenium. The example methods may advantageously yield higher efficiency solar cells.

Thus, in one aspect, a method is provided including the steps of (a) introducing a substrate having a precursor material deposited on a surface of the substrate into a first zone of a vacuum chamber, where the precursor material includes copper, indium, and at least one of gallium, selenium, sulfur, sodium, antimony, boron, aluminum, and silver, (b) within the first zone, heating the precursor material to a target reaction temperature within a range of about 270° C. to about 490° C., (c) maintaining a selenium vapor in a second zone of the vacuum chamber and (d) after heating the precursor material to the target reaction temperature, introducing the precursor material and the substrate to the second zone of the vacuum chamber.

In another aspect, a non-transitory computer readable medium is provided. The non-transitory computer readable medium stores instructions that when executed by a control system cause the control system to perform functions. The functions include introducing a substrate having a precursor material deposited on a surface of the substrate into a first zone of a vacuum chamber. The precursor material includes copper, indium, and at least one of gallium, selenium, sulfur, sodium, antimony, boron, aluminum, and silver. The functions also include, within the first zone, heating the precursor material to a target reaction temperature within a range of about 270° C. to about 490° C. The functions further include maintaining a selenium vapor in a second zone of the vacuum chamber and, after heating the precursor material to the target reaction temperature, introducing the precursor material and the substrate to the second zone of the vacuum chamber.

These as well as other aspects, advantages, and alternatives, will become apparent to those of ordinary skill in the art by reading the following detailed description, with reference where appropriate to the accompanying drawings.

### BRIEF DESCRIPTION OF THE DRAWINGS

FIG. 1 is an illustration of a substrate web including a precursor layer according to one embodiment of the invention.

FIG. 2A is an illustration of a system for processing of precursor materials according to one embodiment.

FIG. 2B depicts an example relationship between (i) a temperature of a substrate web and (ii) elapsed processing time of the substrate web.

FIG. 2C depicts an example relationship between CIGS film roughness and initial reaction temperature.

FIG. 3 is an illustration of a CIGS material formed by selenization of a precursor layer according to one embodiment of the invention.

FIG. 4 is a flow chart of a method according to one embodiment.

### DETAILED DESCRIPTION

Example methods and systems are described herein. Any example embodiment or feature described herein is not necessarily to be construed as preferred or advantageous over other embodiments or features. The example embodiments described herein are not meant to be limiting. It will be readily understood that certain aspects of the disclosed systems and methods can be arranged and combined in a wide variety of different configurations, all of which are contemplated herein.

Furthermore, the particular arrangements shown in the Figures should not be viewed as limiting. It should be understood that other embodiments may include more or less of each element shown in a given Figure. Further, some of the illustrated elements may be combined or omitted. Yet further, an example embodiment may include elements that are not illustrated in the Figures.

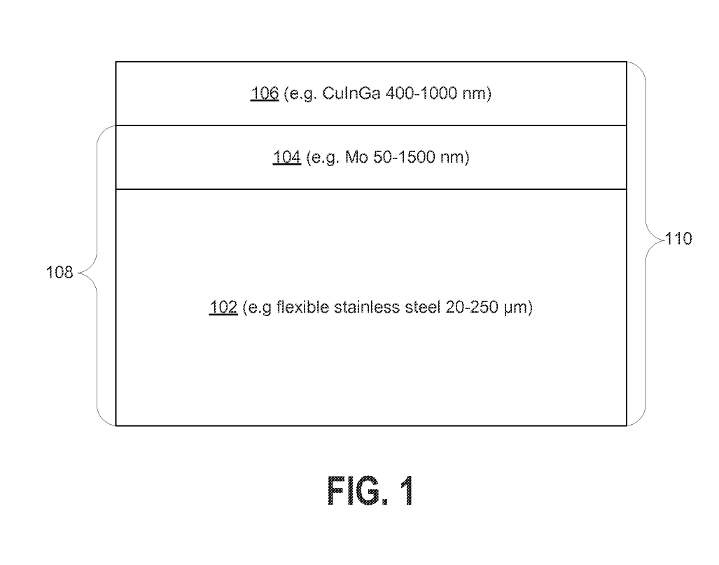

FIG. 1 shows a suitable precursor layer 106 deposited upon an electrode layer 104 that in turn is deposited upon a substrate layer 102. Together the substrate layer 102 and the electrode layer 104 comprise a composite substrate 108. Further, when the precursor layer 106 is deposited on the composite substrate, the resulting structure may be referred to as a substrate web 110.

In one embodiment, the substrate layer 102 may include stainless steel, aluminum, or titanium, among other possibilities. In another embodiment, the substrate layer 102 may be flexible and configured for roll-to-roll processing, having a thickness ranging between about 20 μm to about 250 μm, for example. The substrate layer 102 may have a polished or unpolished top surface with a roughness on the order of about 20 nm to about 100 nm. Other materials, such as the electrode layer 104, may be deposited upon the top surface of the substrate layer 102 as part of a process to form a solar cell or module. The substrate layer 102 may be configured to withstand high temperatures and high rates of temperature change related to material processing techniques disclosed herein. Prior to depositing additional layers, the substrate layer 102 may undergo various chemical rinses or drying methods that remove contaminants from the top surface of the substrate layer 102 that may degrade solar cell performance.

In one embodiment, the electrode layer 104 may include a molybdenum (Mo) film of thickness ranging from about 50 nm to about 1500 nm. Alternatively, the electrode layer 104 may include other conductive metals, such as Cr, Ti, W, Ta, or Nb. The other conductive metal(s) may be included in a sub-layer of the electrode layer 104 that is adjacent to the precursor layer 106. In some examples, the substrate layer 102 and the electrode layer 104 may become part of a solar cell or solar module, and the electrode layer 104 may act as a conductive path (e.g. a positive or negative terminal) used to harness electrical energy generated by the solar cell or module. In one embodiment, the electrode layer 104 may include sputter-deposited Mo having a smooth surface configured to form an electric contact between the electrode layer 104 and a light absorbing layer of a solar cell or module.

The precursor layer 106 may include copper, indium and at least one of gallium, selenium, sulfur, sodium, antimony, boron, aluminum, silver or some combination thereof. In one embodiment, as shown in FIG. 1, the precursor layer 106 may include copper (Cu), indium (In) and gallium (Ga) and may have a thickness ranging from about 400 nm to about 1000 nm. The precursor layer 106 may be homogeneous in that regions of the precursor layer 106 may have a stoichiometry that is substantially consistent with other regions of the precursor layer 106. Within the precursor layer 106, a ratio of (i) copper to (ii) indium and gallium may range from about 0.7 to about 0.96 and a ratio of (i) gallium to (ii) gallium and indium may range from about 0.2 to about 0.4.

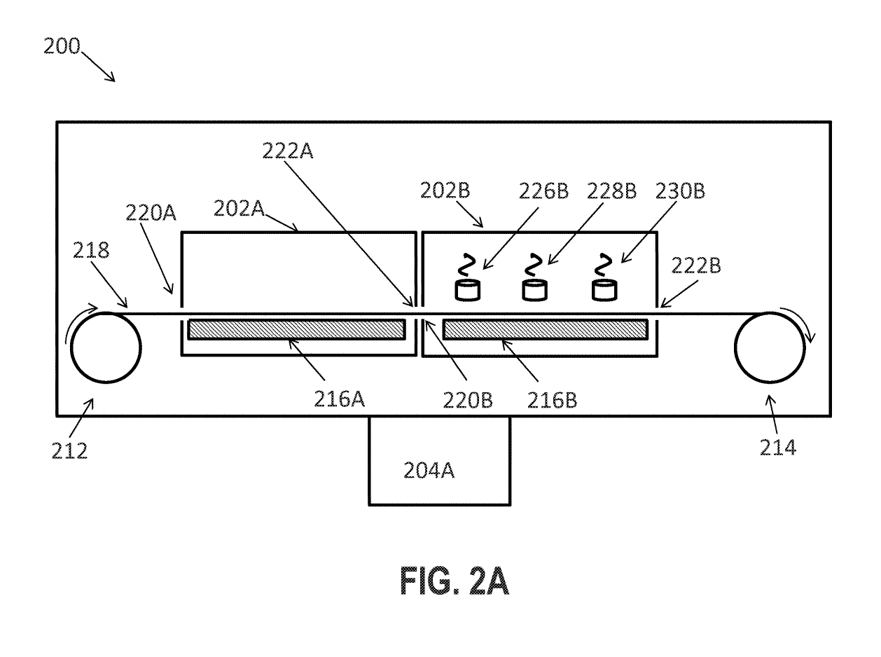

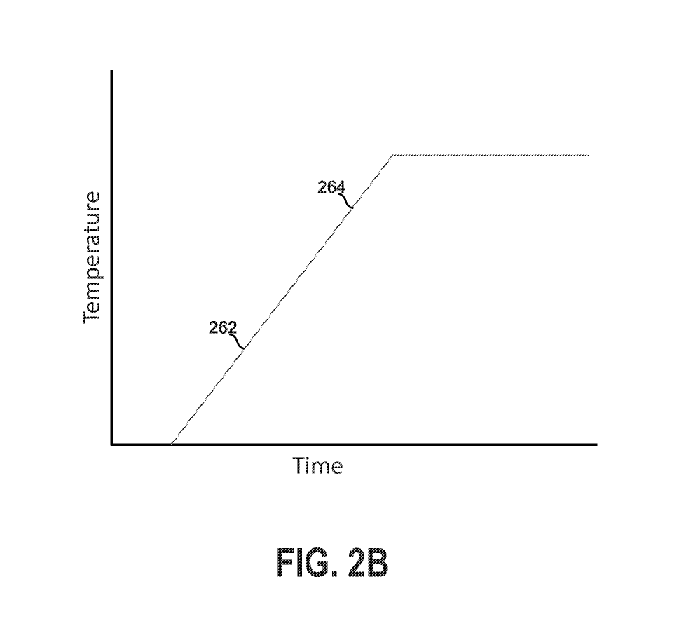

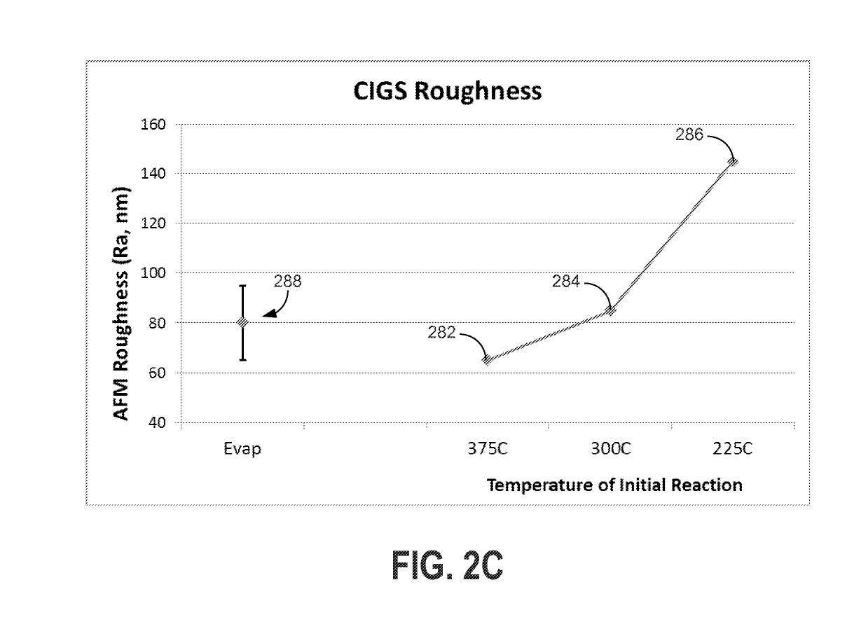

FIG. 2A shows a system for processing of precursor materials. The materials processing system 200 may include a first zone 202A and a second zone 202B. The first zone 202A and the second zone 202B may be disposed in a single vacuum chamber or may be separate vacuum chambers. In one embodiment, the first and second zones 202A and 202B may have independent temperature, pressure and atmosphere control capability. For example, a control system may be configured to monitor and maintain (i) a temperature of a substrate web 218, (ii) an air pressure or (iii) atmospheric contents within the first zone 202A or the second zone 202B. In one embodiment, the control system may be configured to control a first zone heater 216A and a second zone heater 216B to control respective temperatures of the substrate web 218 within the first zone 202A or the second zone 202B. In another embodiment, the control system may control a pump 204A that may be configured to respectively evacuate the first zone 202A and the second zone 202B to pressures on the order of about 10⁻⁵ Torr. (In some embodiments, pumps corresponding to each of the first zone 202A and the second zone 202B may be used.) Other pressure conditions ranging between 10⁻⁶ to 10⁻² Torr are possible. The pump 204A may include one or more mechanical pumps, turbo-molecular pumps, diffusion pumps, ion pumps, or cryopumps, among other possibilities. The control system may also be configured to maintain flow rates of processing gases such as argon, selenium, sulfur, or nitrogen into the first zone 202A or the second zone 202B.

In one embodiment, the substrate web 218 may include (i) a flexible stainless steel substrate layer with a (ii) molybdenum electrode layer deposited upon a top surface of the substrate layer and (iii) a CuInGa precursor layer deposited upon the electrode layer (see FIG. 1 and related description above). Before further material processing of the substrate web 218, at least a portion of the substrate web 218 may be rolled up on a feeding reel 212. The substrate web 218 may be unfurled by the feeding reel 212 and further advanced by a collection reel 214 such that the substrate web 218 may be fed first through the first zone 202A and then the second zone 202B.

The substrate web 218 may be introduced into the first zone 202A, by the control system for example, at a first zone insertion point 220A, which may include a feed-through configured to feed the substrate web 218 into the first zone 202A while maintaining a differential pressure between the first zone 202A and the surrounding atmosphere. While moving through the first zone 202A, the substrate web 218 may be heated by a first zone heater 216A. In one embodiment, the first zone heater 216A may include a halogen lamp heater or a resistive heating element configured to heat the substrate web 218 to a target reaction temperature of ranging from about 270° C. to about 490° C., and preferably ranging from about 360° C. to about 380° C. The collection reel 214 and the feeding reel 212 may be configured to move the substrate web 218 through the first zone 202A at a rate that allows the substrate web 218 to reach the target reaction temperature before the substrate web 218 is removed from the first zone 202A. In one embodiment, the substrate web 218 may be maintained at the target reaction temperature for about three minutes to about thirty minutes in order to complete a reaction that forms CIGS. The first zone 202A may be substantially devoid of selenium, sulfur or other materials that may be vaporized in the second zone 202B, allowing the substrate web 218 to reach the target reaction temperature before being exposed to vapors introduced in the second zone 202B.

Upon reaching a first zone removal point 222A, the substrate web 218 is introduced into the second zone 202B. In one embodiment, the first zone 202A and the second zone 202B may be coupled via slits configured to transition the substrate web 218 from the first zone 202A to the second zone 202B, without substantial exposure of the substrate web 218 to a surrounding atmosphere or vapors before entering the second zone 202B. The substrate web 218 may be introduced into the second zone 202B at a second zone insertion point 220B that may include a feed-through similar to the first zone insertion point 220A or the first zone removal point 222A.

Once inside the second zone 202B, the substrate web 218 may be exposed to a vapor released by the vapor sources 226B, 228B, 230B, for example. In various embodiments, there may be more or less than three vapor sources within the second zone 202B. Also, the vapor sources 226B, 228B, 230B may be located within the second zone 202B, as shown in FIG. 2A, or may be located outside of the second zone 202B. In examples where the vapor sources 226B, 228B, and 230B are located outside of the second zone 202B, the vapor sources 226B, 228B, 230B may be connected to the second zone 202B via piping and valves controlled by the control system, for example. In another embodiment, the vapor released by the vapor sources 226B, 228B, 230B may be selenium or sulfur, among other possibilities, and is preferably selenium. The vapor sources 226B, 228B, 230B may be heated vessels containing selenium shot that are heated to cause the selenium to vaporize and diffuse throughout the second zone 202B. In one example, the temperature of the selenium within the vessels may be heated to, and maintained at, about 335° C. The substrate web 218 may be inserted into the second zone 202B once the substrate web 218 reaches a target reaction temperature ranging from about 270° C. to about 490° C., and preferably ranging from about 360° C. to about 380° C. In one embodiment, the substrate web 218 may first come into contact with the vapor in the second zone 202B while the substrate web 218 is at the target reaction temperature. Then a temperature of the substrate web 218 within the second zone 202B may be increased to at least about 520° C., via the second zone heater 216B, after the substrate web 218 comes into contact with the vapor released by the vapor sources 226B, 228, and 230B. The resulting CIGS films may have an average roughness of about 65 nm.

The substrate web 218 may be removed from the second zone 202B at the second zone removal point 222B, which may include a slit similar to the second zone insertion point 220B. In one example, a portion of the substrate web 218, after being removed from the second zone 202B, may be cooled to an ambient or lower temperature on the order of about 20° C. to about 150° C. before being rolled up on the collection reel 214. In another example, the system 200 may include a third zone (not shown) in which the substrate web 218 may cool to an ambient temperature under vacuum and outside the presence of the vapor in the second zone 202B.

FIG. 2B depicts an example relationship between (i) a temperature of a substrate web and (ii) elapsed processing time of the substrate web. Point 262 depicts a scenario in which reactive vapor may be introduced to the substrate web 218 while the substrate web 218 is below the target reaction temperature. For example, the vapor may be introduced while the substrate web 218 is at a temperature of 200° C. This may result in formation of a rough CIGS film. Point 264 depicts a scenario in which reactive vapor may be introduced to the substrate web 218 while the substrate web 218 is at or above the target reaction temperature. In one embodiment, for example, the vapor may be introduced while the substrate web 218 has a temperature of 375° C. This embodiment may result in formation of a smooth CIGS film.

FIG. 2C depicts an example relationship between CIGS film roughness and initial reaction temperature. Point 282 represents CIGS films produced by bringing a substrate web into contact with selenium vapor after heating the substrate web to about 375° C. Such films have an average roughness of approximately 65 nm. Point 284 represents CIGS films produced by bringing a substrate web into contact with selenium vapor after heating the substrate web to about 300° C. Such films have an average roughness of approximately 85 nm. Point 286 represents CIGS films produced by bringing a substrate web into contact with selenium vapor after heating the substrate web to about 225° C. Such films have an average roughness of approximately 145 nm. Point 288 provides a point of comparison, in that CIGS films produced using known evaporation techniques generally have a roughness ranging from approximately 65 nm to 95 nm. Accordingly, FIG. 2C shows that raising the temperature of the CIGS substrate web to around 375° C. before exposing the substrate web to selenium vapor yields CIGS films that are at least as smooth as films produced via co-evaporation.

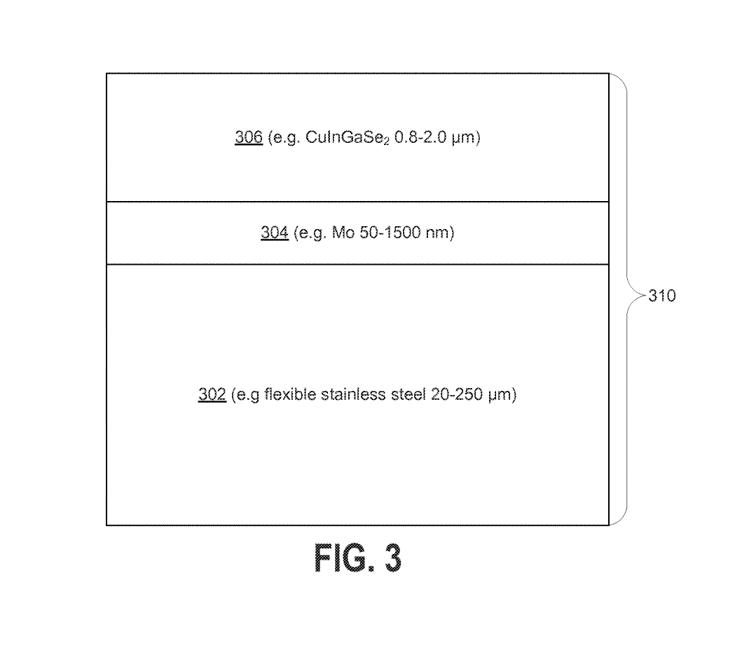

FIG. 3 shows a CIGS material formed by selenization of a precursor layer. FIG. 3 includes a substrate layer 302, an electrode layer 304, and a reaction product layer 306, collectively making up a substrate web 310.

The substrate layer 302 and the electrode layer 304 may respectively be similar to the substrate layer 102 and the electrode layer 104 of FIG. 1 as described above. The substrate layer 302 and the electrode layer 304 may have been exposed to the processing environment or methods described with respect to FIG. 2A above, but typically remain substantially unchanged by the processing environment or methods. In some embodiments, a portion of the electrode layer 304 may react with Se vapor to form MoSe₂, for example. Thus, under certain conditions, the precursor layer 106 of FIG. 1 may react with a vapor, thereby substantially consuming the precursor layer 106 and forming the reaction product layer 306. For example, a CuInGa precursor layer may react with Se vapor to form a CuInGaSe₂ reaction product layer 306.

In one embodiment, the reaction product layer 306 may be a CuInGaSe₂ (CIGS) layer formed by selenization of the precursor layer 106 of FIG. 1. That is, the precursor layer 106, comprising Cu, In, and Ga, may be substantially converted by reactive processes described in relation to FIG. 2A above, to form CIGS. In doing so, a resultant thickness of the reaction product layer 306 (CIGS) may be approximately two times larger than a thickness of the precursor layer 106 of FIG. 1. In other embodiments, the reaction product layer 306 may include materials such as aluminum or boron in place of gallium, and a material such as sulfur in place of selenium.

The substrate web 310 comprising the substrate layer 302 (e.g. stainless steel), the electrode layer 304 (e.g. molybdenum), and the reaction product layer 306 (e.g. a CIGS light-absorbing layer) may be configured for further processing or deposition of additional functional layers, such as a buffer layer of cadmium sulfide, a transparent conductive oxide layer such as aluminum doped zinc oxide, or a metal contact grid layer such as nickel, aluminum, silver or copper for completing a circuit between the molybdenum electrode layer and the metal contact grid layer.

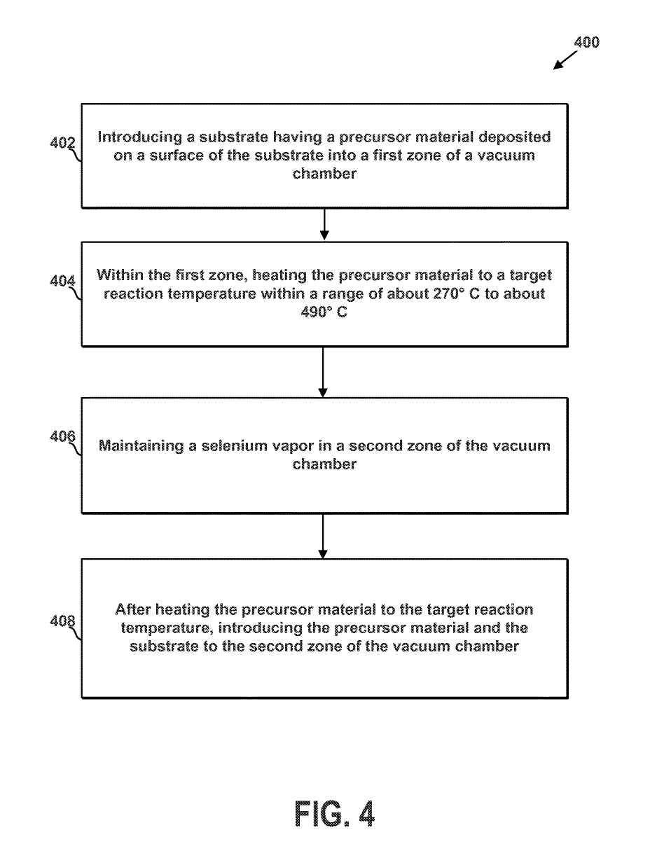

FIG. 4 is a flow chart representing an example method for processing a precursor material. Method 400 may include one or more functions as illustrated by blocks 402-408. Although the blocks are illustrated in a sequential order, these blocks may in some instances be performed in parallel, and/or in a different order than those described herein. Also, the various blocks may be combined into fewer blocks, divided into additional blocks, and/or removed based on the desired implementation.

In addition, for the method 400 and other processes and methods disclosed herein, FIG. 4 shows functionality and operation of one possible implementation of present embodiments. In this regard, each block may represent a module, a segment, or a portion of program code, which includes one or more instructions executable by a processor for implementing specific logical functions or steps in the process. The program code may be stored on any type of computer readable medium, for example, such as a storage device including a disk or hard drive. The computer readable medium may include a non-transitory computer readable medium, for example, such as computer-readable media that stores data for short periods of time like register memory, processor cache, and random access memory (RAM). The computer readable medium may also include non-transitory media, such as secondary or persistent long term storage, like read-only memory (ROM), optical or magnetic disks, or compact-disc read-only memory (CD-ROM), for example. The computer readable media may also be any other volatile or non-volatile storage system. The computer readable medium may be considered a computer readable storage medium, a tangible storage device, or other article of manufacture, for example.

In addition, for the method 400 and other processes and methods disclosed herein, each block in FIG. 4 may represent circuitry that is configured to perform the specific logical functions of the method 400. At block 402, method 400 includes introducing a substrate having a precursor material deposited on a surface of the substrate into a first zone of a vacuum chamber. The precursor material may include copper, indium, and at least one of gallium, selenium, sulfur, sodium, antimony, boron, aluminum, silver or some combination thereof. The first zone of the vacuum chamber may be a portion of a vacuum system that has independent substrate temperature control. Then, at block 404, method 400 further includes heating the precursor material to a target reaction temperature within a range of about 270° C. to about 490° C. within the first zone. In one embodiment, the target reaction temperature may range from about 360° C. to about 380° C., preferably about 370° C. In one embodiment, the precursor material may be heated to the target reaction temperature by the first zone heater 216A, described above in relation to FIG. 2A. Then, at block 406, method 400 includes maintaining a selenium vapor or sulfur vapor in a second zone of the vacuum chamber. The selenium vapor may be Se or H₂Se and the sulfur vapor may be S or H₂S. The selenium vapor may be maintained within the second zone 202B by the vapor sources 226B, 228B, and 230B of FIG. 2A, for example. Method 400 also, includes, at block 408, introducing the precursor material and the substrate to the second zone of the vacuum chamber, after heating the precursor material to the target reaction temperature.

In one embodiment, method 400 may further include increasing a temperature of the substrate (i.e. the substrate layer, the electrode layer, a reaction product layer, or any remaining precursor layer) to about 520° C. or more while the substrate is within the second zone. For example, the temperature of the substrate may be increased by the second zone heater 216B. Once introduced into the second zone of the vacuum chamber, the precursor material may react with the selenium vapor or the sulfur vapor.

The above detailed description describes various features and functions of the disclosed systems and methods with reference to the accompanying figures. While various aspects and embodiments have been disclosed herein, other aspects and embodiments will be apparent to those skilled in the art. All embodiments within and between different aspects of the invention can be combined unless the context clearly dictates otherwise. The various aspects and embodiments disclosed herein are for purposes of illustration and are not intended to be limiting, with the true scope and spirit being indicated by the following claims.

1. A method comprising:
introducing a substrate having a precursor material deposited on a surface of the substrate into a first zone of a vacuum chamber, wherein the precursor material comprises copper, indium, at least one of selenium and sulfur, and optionally gallium, sodium, antimony, boron, aluminum, or silver;
within the first zone, heating the precursor material to a target reaction temperature within a range of about 270° C. to about 490° C.;
maintaining one of a selenium vapor or a sulfur vapor in a second zone of the vacuum chamber; and
after heating the precursor material to the target reaction temperature, introducing the precursor material and the substrate to the second zone of the vacuum chamber.

2. The method of claim 1, further comprising reacting the precursor material with the selenium vapor or the sulfur vapor in the second zone of the vacuum chamber.

3. The method of claim 1, wherein the target reaction temperature is within a range of about 360° C. to about 380° C.

4. The method of claim 1, wherein a temperature of the substrate is increased to at least about 520° C. within the second zone.

5. The method of claim 1, wherein the vacuum chamber is configured for roll-to-roll processing and the substrate comprises stainless steel, non-stainless steel, aluminum or other metal films.

6. The method of claim 1, wherein the target reaction temperature is within a range of about 350° C. to about 490° C.

7. The method of claim 1, wherein the target reaction temperature is about 370° C.

8. The method of claim 1, further comprising controlling the amount of selenium vapor or sulfur vapor in the second zone via a valve in communication with the second zone of the vacuum chamber and with a vessel containing a molten form of selenium or sulfur.

9. The method of claim 8, further comprising maintaining a temperature of the vessel at about 335° C.

10. The method of claim 1, wherein the selenium vapor includes H₂Se or the sulfur vapor includes H₂S.

11. A non-transitory computer readable medium storing instructions that when executed by a control system cause the control system to perform functions comprising:
introducing a substrate having a precursor material deposited on a surface of the substrate into a first zone of a vacuum chamber, wherein the precursor material comprises copper, indium, at least one of selenium and sulfur, and optionally gallium, sodium, antimony, boron, aluminum, or silver;
within the first zone, heating the precursor material to a target reaction temperature within a range of about 270° C. to about 490° C.;
maintaining one of a selenium vapor or a sulfur vapor in a second zone of the vacuum chamber; and
after heating the precursor material to the target reaction temperature, introducing the precursor material and the substrate to the second zone of the vacuum chamber.

12. The non-transitory computer readable medium of claim 11, wherein the target reaction temperature is within a range of about 360° C. to about 380° C.

13. The non-transitory computer readable medium of claim 11, wherein a temperature of the substrate is increased to about 520° C. within the second zone.

14. The non-transitory computer readable medium of claim 11, wherein the target reaction temperature is within a range of about 350° C. to about 490° C.

15. The non-transitory computer readable medium of claim 11, wherein the functions further comprise reacting the precursor material with the selenium vapor or the sulfur vapor in the second zone of the vacuum chamber.

16. A method according to claim 2, wherein the target reaction temperature is within a range of about 360° C. to about 380° C.

17. A method according to claim 16, wherein a temperature of the substrate is increased to at least about 520° C. within the second zone.

18. A method according to claim 17, wherein the vacuum chamber is configured for roll-to-roll processing and the substrate comprises stainless steel, non-stainless steel, aluminum or other metal films.

19. A method according to claim 18, further comprising controlling the amount of selenium vapor or sulfur vapor in the second zone via a valve in communication with the second zone of the vacuum chamber and with a vessel containing a molten form of selenium or sulfur.

20. A method according to claim 19, wherein the selenium vapor includes H₂Se or the sulfur vapor includes H₂S, and the method further comprises maintaining a temperature of the vessel at about 335° C.
